(19) United States
(12) Patent Application Publication
(10) Pub. No.: US 2025/0314484 A1
(43) Pub. Date: Oct. 9, 2025

(54) SAMPLE SURFACE QUALITY MANAGEMENT DEVICE

(71) Applicant: HITACHI HIGH-TECH CORPORATION, Minato-ku, Tokyo (JP)

(72) Inventors: Masato ISHIZUKA, Tokyo (JP); Toshifumi HONDA, Tokyo (JP); Ryuji UKAI, Tokyo (JP); Kenshiro OHTSUBO, Tokyo (JP)

(21) Appl. No.: 18/865,547

(22) PCT Filed: Aug. 10, 2022
(86) PCT No.: PCT/JP2022/030592

§ 371 Date: Nov. 13, 2024

(51) Int. Cl. G01B 11/30

(52) U.S. Cl. CPC G01B 11/303

(57) ABSTRACT

Provided is a sample surface quality management device that measures a micro roughness of a sample. The sample surface quality management device includes: a scattered light measurement device that measures scattered light generated on the sample; an interference light measurement device that measures interference light including reflected light generated on the sample; and a signal processing device that processes signals of the scattered light measurement device and the interference light measurement device. The signal processing device calculates a first evaluation value of the micro roughness of the sample based on the signal of the interference light measurement device, calculates a scattering characteristic signal based on the signal of the scattered light measurement device, and calculates, for a spatial frequency band for which the first evaluation value is not calculated, a second evaluation value of the micro roughness based on the first evaluation value and the scattering characteristic signal.

### TECHNICAL FIELD

The present invention relates to a sample surface quality management device that measures a micro roughness of a sample such as a wafer in a semiconductor device manufacturing process and the like and manages quality of a sample surface.

### BACKGROUND ART

With higher integration of semiconductor devices, higher quality of silicon wafers is required. As one element related to quality of a wafer, it is important to inspect the entire surface of all samples in the in-line inspection in a wafer manufacturing process for surface roughness affecting electrical characteristics of the device. The micro roughness of the sample, in other words, a microscopic flatness of the sample surface is generally measured by an atomic force microscope (AFM). However, since the AFM requires a time for measurement, it is difficult to introduce into the in-line inspection.

As a technique for measuring a micro roughness by in-line inspection, there is known a technique for measuring a micro roughness based on a haze value, which is measured by a scattered light measurement device used for foreign matter inspection on a sample surface, by using a correlation between the haze value and the micro roughness (PTL 1).

### CITATION LIST

### Patent Literature

PTL 1: JP6043813

### SUMMARY OF INVENTION

### Technical Problem

However, since the haze value changes depending on various conditions such as a material of a sample, a state and a mechanical difference of an optical system of an inspection device, and the like, there is a problem in quantitatively evaluating the micro roughness. On the other hand, in the technique disclosed in PTL 1, the haze value is calibrated in comparison with a measurement result obtained in advance by an AFM. In this case, when conditions such as the material of the sample affecting the haze value are changed, it is necessary to perform calibration work by performing preliminary measurement with the AFM every time, and the number of steps increases.

An object of the invention is to provide a sample surface quality management device capable of measuring a micro roughness of the entire sample surface at a high speed.

### Solution to Problem

To achieve the above object, the invention provides a sample surface quality management device for measuring a micro roughness of a sample. The sample surface quality management device includes: a stage device configured to hold the sample and move the sample in a sample surface direction; a scattered light measurement device configured to measure scattered light generated on the sample; an interference light measurement device configured to measure interference light including reflected light generated on the sample; and a signal processing device configured to process signals of the scattered light measurement device and the interference light measurement device. The signal processing device calculates a first evaluation value of the micro roughness of the sample based on the signal of the interference light measurement device, calculates a scattering characteristic signal based on the signal of the scattered light measurement device, and calculates, for a spatial frequency band for which the first evaluation value is not calculated, a second evaluation value of the micro roughness based on the first evaluation value and the scattering characteristic signal.

### Advantageous Effects of Invention

According to the invention, it is possible to measure a micro roughness of the entire sample surface at a high speed.

### BRIEF DESCRIPTION OF DRAWINGS

FIG. 1 is a schematic diagram of a sample surface quality management device according to a first embodiment of the invention.

FIG. 2 is a diagram showing an example of a scanning trajectory of a sample in the sample surface quality management device according to the first embodiment of the invention.

FIG. 3 is a schematic diagram showing a configuration example of a scattered light intensity measurement system provided in the sample surface quality management device according to the first embodiment of the invention.

FIG. 4 is a schematic diagram showing a positional relationship between a beam spot and the scattered light intensity measurement system provided in the sample surface quality management device according to the first embodiment of the invention.

FIG. 5 is a diagram showing an example of an output signal (scattered light signal) of the scattered light intensity measurement system provided in the sample surface quality management device according to the first embodiment of the invention.

FIG. 6 is a schematic diagram showing a configuration example of an interference light measurement device provided in the sample surface quality management device according to the first embodiment of the invention.

FIG. 7 is a flowchart showing an example of a procedure of processing of evaluating a micro roughness of the sample by a signal processing device provided in the sample surface quality management device according to the first embodiment of the invention.

FIG. 8 is a diagram showing a spatial frequency band that cannot be measured by DIC measurement of the sample surface quality management device according to the first embodiment of the invention.

FIG. 9A is a diagram showing a function used as a model (first model) of a PSD.

FIG. 9B is a diagram showing a function used as a model (second model) of the PSD.

FIG. 9C is a diagram showing a function used as a model (third model) of the PSD.

FIG. 10A is a diagram showing a procedure for calculating a second evaluation value based on a first evaluation value and a scattering characteristic signal in the first embodiment of the invention.

FIG. 10B is a diagram showing a procedure for calculating the second evaluation value based on the first evaluation value and the scattering characteristic signal in the first embodiment of the invention.

FIG. 11A is a diagram showing a first example of handling a haze value whose spatial direction is different from that of the first evaluation value.

FIG. 11B is a diagram showing a second example of handling a haze value whose spatial direction is different from that of the first evaluation value.

FIG. 11C is a diagram showing a third example of handling a haze value whose spatial direction is different from that of the first evaluation value.

FIG. 12 is a diagram showing PSD data calculation in a direction orthogonal to a shear direction.

FIG. 13 is a schematic diagram showing a configuration example of an interference light measurement device provided in a sample surface quality management device according to a second embodiment of the invention.

FIG. 14A is a diagram showing a procedure for calculating a second evaluation value based on a first evaluation value and a scattering characteristic signal in the second embodiment of the invention.

FIG. 14B is a diagram showing a procedure for calculating the second evaluation value based on the first evaluation value and the scattering characteristic signal in the second embodiment of the invention.

FIG. 15 is a schematic diagram showing a configuration example of an interference light measurement device provided in a sample surface quality management device according to a third embodiment of the invention.

FIG. 16 is a diagram showing a spatial frequency band that cannot be measured by DIC measurement of the sample surface quality management device according to the third embodiment of the invention.

FIG. 17 is a schematic diagram showing a configuration example of a scattered light intensity measurement system provided in a sample surface quality management device according to a fourth embodiment of the invention.

FIG. 18 is a conceptual diagram showing a state in which beam spots partially overlap between adjacent scanning trajectories.

FIG. 19A is a schematic diagram showing a configuration example of a detection optical system of a scattered light device provided in a sample surface quality management device according to a fifth embodiment of the invention.

FIG. 19B is a diagram showing a relationship between an emission direction of scattered light and pixel coordinates on a pupil surface in the detection optical system of the scattered light measurement device provided in the sample surface quality management device according to the fifth embodiment of the invention.

FIG. 20A is a diagram showing a display example in which a processing result is shown in a surface map of a sample 1 for each display unit region.

FIG. 20B is a diagram showing a display example in which a processing result is shown by a histogram.

FIG. 20C is a diagram showing a display example in which a processing result (PSD data) is shown in a scatter diagram.

FIG. 20D is a diagram showing a display example in which a processing result (model parameters) is shown in a table format.

### DESCRIPTION OF EMBODIMENTS

Hereinafter, embodiments of the invention will be described with reference to the drawings.

### First Embodiment

### [Sample Surface Quality Management Device]

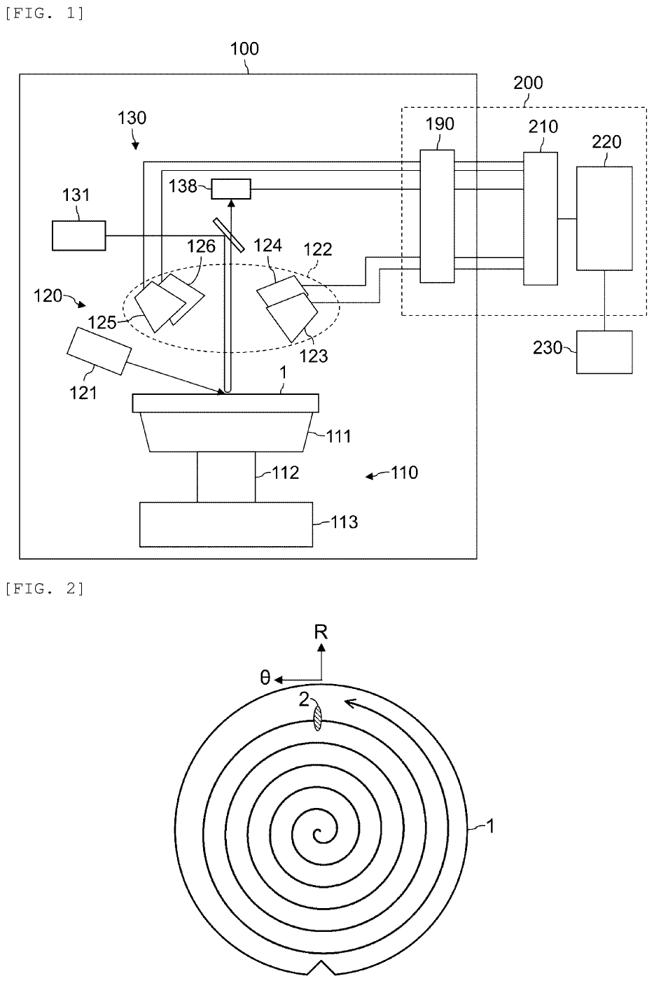

FIG. 1 is a schematic diagram of a sample surface quality management device according to a first embodiment of the invention. The sample surface quality management device in the figure includes an inspection device 100 and a signal processing device 200. A representative example of a sample 1 in which the sample surface quality management device inspects and manages a micro roughness, in other words, a microscopic flatness of the surface, is a disk-shaped semiconductor silicon wafer in which no pattern is formed and the surface is flat.

### [Inspection Device 100]

The inspection device 100 includes an optical system that measures scattered light generated on a surface of the sample 1, and an optical system that measures a surface shape of the sample 1. A method of measuring the surface shape of the sample 1 is interference light measurement capable of measuring the entire surface of the sample at a high speed. The interference light measurement includes, for example, an optical interference shape measurement method, a phase shift interference shape measurement method, and a wavelength shift interference shape measurement method, and any method may be adopted. Specifically, the inspection device 100 includes a stage device 110, a scattered light measurement device 120, an interference light measurement device 130, and a signal processing unit 190.

### [Stage Device 110]

The stage device 110 is a device that holds the sample 1 and moves the sample 1 in a sample surface direction with respect to a beam spot, and includes a sample stage 111, a rotation stage 112, and a straight advancing stage 113. The sample stage 111 is, for example, a chuck table for holding the sample 1 by aspiration and the like. The rotation stage 112 moves straightly in a radial direction of the sample 1 by the straight advancing stage 113, and the sample stage 111 rotates by the rotation stage 112.

FIG. 2 is a diagram showing an example of a scanning trajectory of a sample. The surface of the sample 1 is irradiated with light from the scattered light measurement device 120 and the interference light measurement device 130, and a beam spot 2 is formed. The beam spot 2 shown in the figure is one in which beam spots of both the scattered light measurement device 120 and the interference light measurement device 130 are formed at substantially the same coordinates (or coordinates within a predetermined distance from each other). During the inspection, the sample 1 is rotationally driven in a circumferential direction of the sample 1 by the rotation stage 112, and the beam spot 2 rotates in an arrow θ direction on the surface of the sample 1. The sample 1 is driven straightly by the straight advancing stage 113, and at the same time, the beam spot 2 moves straightly in an arrow R direction on the surface of the sample 1. From a combination of the rotation operation and the straight advancing operation, the stage device 110 moves the sample 1 with respect to the beam spot 2, and the beam spot 2 scans the entire surface of the sample 1 while drawing a spiral trajectory.

Although not shown in FIGS. 1 and 2, the stage device 110 may include a straight advancing stage having a movement axis (here, an X axis) of the straight advancing stage 113 and a movement axis (here, a Y axis) intersecting with a horizontal direction. In this case, the sample 1 can be scanned by a trajectory in which the movement of the beam spot 2 in an X direction and the movement in a-X direction are repeated while sequentially shifting in a Y axis direction.

### [Scattered Light Measurement Device 120]

The scattered light measurement device 120 is an optical system that illuminates the sample 1 and measures scattered light generated at the beam spot 2 on the sample surface, and includes an illumination optical system 121 and a detection optical system 122.

The illumination optical system 121 is an optical system that includes a light source for scattered light and guides the light emitted from the light source to the beam spot 2, and includes a plurality of optical elements such as lenses. In the embodiment, the illumination optical system 121 can perform oblique illumination for obliquely irradiating the surface of the sample 1 with light. The illumination optical system 121 may include a mechanism for switching an optical path to vertical illumination for irradiating the surface of the sample 1 with light perpendicularly.

The detection optical system 122 is an optical system that segments and detects the scattered light generated at the beam spot 2 on the sample surface in a spatial direction. In the embodiment, the detection optical system 122 includes a plurality of scattered light intensity measurement systems 123 to 126 (four are shown in FIG. 1) having different azimuthal angles and elevation angles with respect to the beam spot 2.

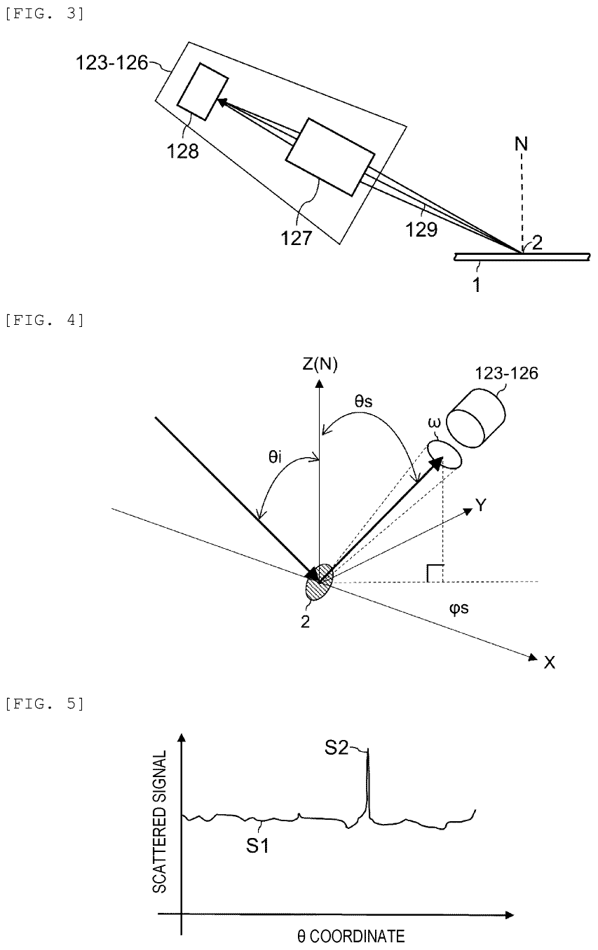

FIG. 3 is a schematic diagram showing a configuration example of the scattered light intensity measurement systems 123 to 126. The scattered light intensity measurement systems 123 to 126 include a detection optical system 127 and a scattered light sensor 128.

The detection optical system 127 includes a plurality of lenses (lens group), and constitutes a so-called condensing optical system or an imaging optical system. The detection optical system 127 may include a spatial filter or a polarization filter, and may have a function of shielding undesirable light as noise. The beam spot 2 is positioned on an extension line of an optical axis 129 of the detection optical system 127. The optical axes 129 of the scattered light intensity measurement systems 123 to 126 extend in different spatial directions from the beam spot 2. The optical axes 129 of the scattered light intensity measurement systems 123 to 126 are inclined with respect to a normal line N of the sample surface passing through the beam spot 2 (intersect with the normal line N at the beam spot 2). However, a scattered light intensity measurement system in which the optical axis 129 is coincident or parallel to the normal line N may be provided in the inspection device 100.

The scattered light sensor 128 is a photoelectric conversion element, preferably has a high gain in order to measure weak scattered light, and can use a photomultiplier tube or an avalanche photodiode array. In addition, a photon counting array and the like in which a plurality of photon counting elements are arranged can also be applied to the scattered light sensor 128. As a sensor type, a photomultiplier tube, a SiPM, a CMOS sensor, a CCD, and the like can be used.

FIG. 4 is a schematic diagram showing a positional relationship between the scattered light intensity measurement systems 123 to 126 and the beam spot 2. When a position on the surface of the sample 1 is represented by two-dimensional coordinates (X, Y), a projection direction of an incident optical axis incident at an elevation angle θi (a center line of the light incident on the beam spot 2 from the illumination optical system 121) onto an XY plane is taken as the X axis. The detection optical system 127 having a numerical aperture corresponding to a solid angle ω is positioned at an elevation angle θs and in a direction of an azimuthal angle φs with respect to the beam spot 2. A combination of the elevation angle θs and the azimuthal angle φs is different for each of the scattered light intensity measurement systems 123 to 126. Among the scattered light generated at the beam spot 2, a scattered light flux emitted from the beam spot 2 to a range of the solid angle ω of the azimuthal angle φs at the elevation angle θs is measured by the scattered light intensity measurement system arranged in the direction. In each of the scattered light intensity measurement systems 123 to 126, the scattered light condensed by the detection optical system 127 is photoelectrically converted into a current signal or a voltage signal by the scattered light sensor 128, and is further AD-converted and processed by the signal processing unit 190 (FIG. 1).

### —Example of Scattered Light Signal—

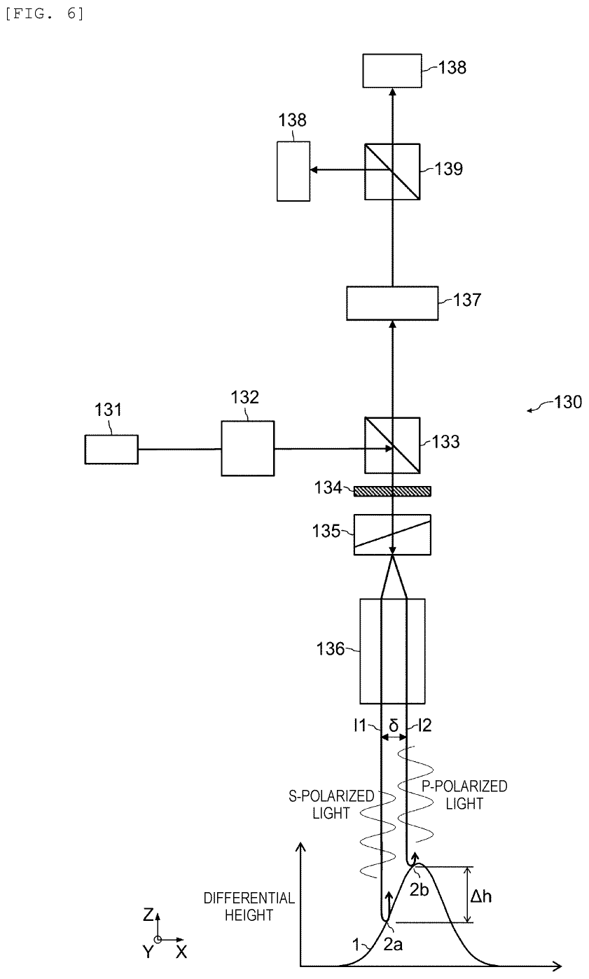

FIG. 5 is a diagram showing an example of an output signal (scattered light signal) of each of the scattered light intensity measurement systems 123 to 126. A horizontal axis of FIG. 5 is a θ coordinate on the sample surface along the spiral trajectory of the beam spot 2 shown in FIG. 2, and corresponds to time. A vertical axis of FIG. 5 is a magnitude of the scattered light signal output from the scattered light sensor 128. The scattered light caused by the micro roughness of the sample 1 is incident on the scattered light intensity measurement systems 123 to 126, and a scattered light signal S1 having a waveform as shown in FIG. 5 is obtained in each of the scattered light intensity measurement systems 123 to 126. A data set of a value of the scattered light signal S1 and the θ coordinate is stored in, for example, the signal processing unit 190 for each of the scattered light intensity measurement systems 123 to 126. In addition, when the beam spot 2 crosses a defect (foreign matter and the like), a defect signal S2 which is a particularly large scattered light signal S1 is detected. The defect signal S2 is separated from the scattered light signal S1 by, for example, a high-pass filter (HPF) in the signal processing unit 190. The value and coordinate as a defect detection signal are stored in, for example, the signal processing unit 190.

As a method of separating the defect signal S2 from the scattered light signal S1, it is also possible to adopt a method of separating the signal by the magnitude of the signal in addition to the method of separating the signal by a frequency region like the high-pass filter (HPF). That is, this is a method in which a signal equal to or smaller than a preset threshold is determined as the scattered light signal caused by the micro roughness, and a signal exceeding the threshold is determined as the defect signal S2. The threshold can be set to a predetermined fixed value, and can be set in real-time based on a signal that can be clearly determined to be the defect signal S2.

In addition, as long as the scattered light signal S1 caused by the micro roughness is extracted, it is not necessary to separate the defect signal S2. For example, a method of averaging (merging) the scattered light signals S1 of the scattered light intensity measurement systems 123 to 126 at predetermined time intervals or for each predetermined region on the sample surface can be applied. As the averaging method, an example is shown in which the scattered light intensity measurement systems 123 to 126 are grouped, and the scattered light signals S1 are averaged for each group. As a specific example, the scattered light intensity measurement systems 123 and 126 are set as a first group, and the scattered light intensity measurement systems 124 and 125 are set as a second group, and the scattered light signals S1 are averaged for each group. A pattern of a combination of the scattered light intensity measurement systems 123 to 126 can be freely changed. A combination that accurately reflects a change in the scattered light signal S1 caused by the micro roughness is desirable.

In addition, when a sampling interval of the scattered light signal S1 is sufficiently short, a ratio of the defect signal S2 to the entire scattered light signal S1 is extremely small. In this case, even when the defect signal S2 is larger than the scattered light signal S1, even if the scattered light signal S1 including the defect signal S2 is averaged, the average value hardly changes and can be substantially regarded as an averaged value excluding the defect signal S2. When the scattered light signal S1 is averaged, there is an advantage that a processing load of the signal processing unit 190 is reduced.

### [Interference Light Measurement Device 130]

FIG. 6 is a schematic diagram showing a configuration example of the interference light measurement device 130. The interference light measurement device 130 is an optical system that measures the interference light including the reflected light generated at the beam spot 2 of the sample 1 and measures the surface shape of the sample 1. In the embodiment, the interference light measurement device 130 that detects a differential interference contrast (DIC) and calculates a height of the sample surface will be described as an example.

The interference light measurement device 130 forms the beam spot 2 including two polarization illumination spots of light having different polarizations on the sample surface, and condenses reflected light from the two polarization illumination spots to generate an image of the interference light. Specifically, the interference light measurement device 130 includes a light source 131, a differential interference illumination system 132, a beam splitter 133, a ¼-wavelength plate 134, a Nomarski prism 135, an objective lens 136, an imaging lens 137, and an interference light sensor 138.

The light emitted from the light source 131 passes through the differential interference illumination system 132 including a beam spot shaping unit and an illumination lens. The light passing through the differential interference illumination system 132 is linearly polarized light. The light that has passed through the differential interference illumination system 132 is incident on the ¼-wavelength plate 134 through the beam splitter 133. The ¼-wavelength plate 134 is disposed such that a fast axis is at an angle of 45° with respect to an incident polarization direction. The light passing through the ¼-wavelength plate 134 is circularly polarized light. The light that has passed through the ¼-wavelength plate 134 is incident on the Nomarski prism 135.

The Nomarski prism 135 is made of an optical material having birefringence, and separates, in, for example, the X direction, incident light of the circularly polarized light into two pieces of linearly polarized light 11 and 12 having vibration surfaces orthogonal to each other. The pieces of linearly polarized light 11 and 12 are, for example, S-polarized light and P-polarized light. The pieces of linearly polarized light 11 and 12 separated by the Nomarski prism 135 are incident on the objective lens 136 for DIC. The objective lens 136 is mounted on a stage (not shown), and a pupil position coincides with a separation position of the Nomarski prism 135. The two pieces of linearly polarized light 11 and 12 having passed through the objective lens 136 travel in parallel, and are emitted perpendicularly to the sample surface to form the beam spot 2 including two polarization illumination spots 2a and 2b.

The Nomarski prism 135 is movable in the X direction by a driving mechanism (not shown), and can adjust a phase difference between beams of the separated straight line changes 11 and 12 by adjusting the position of the Nomarski prism 135 in the X direction. In addition, separation width of the pieces of linearly polarized light 11 and 12 is referred to as a shear amount d.

As shown exaggeratedly in FIG. 6, when there is a difference in level between the polarization illumination spots 2a and 2b, that is, a difference in height in a traveling direction of the pieces of linearly polarized light 11 and 12, the phase difference between the pieces of linearly polarized light 11 and 12 changes. In the DIC measurement, when the shear amount d is large, a contrast increases, but a difference in height, which can be measured, per unit distance in the horizontal direction decreases. In the embodiment, the contrast is emphasized, and the shear amount d is set larger than an optical resolution and a sampling interval of the interference light measurement device 130.

In the DIC measurement, the difference in height (differential height Δh) between the polarization illumination spots 2a and 2b is measured based on the phase difference between the pieces of linearly polarized light 11 and 12 reflected on the surface of the sample 1. The pieces of linearly polarized light 11 and 12 reflected on the sample surface are collimated by the objective lens 136, are re-synthesized into the same optical path by the Nomarski prism 135 to become interference light, and are incident on the interference light sensor 138 through the imaging lens 137. In the embodiment, a polarization beam splitter 139 is disposed at a rear stage of the imaging lens 137, the interference light is separated into two orthogonal polarization directions, and interference intensities of the two pieces of interference light are measured by the different interference light sensors 138.

The interference light sensor 138 is a photoelectric conversion element similar to the scattered light sensor 128. Since the directly reflected light from the sample surface is detected, a gain may be lower than that in the scattered light sensor 128. The interference light sensor 138 can adopt a point sensor, an area sensor, or a multi-line sensor. The sensor type can adopt a photomultiplier tube, a SiPM, a CMOS sensor, a CCD, and the like. Since the interference intensity of the interference light changes according to the differential height Δh, the interference intensity of the interference light measured by the interference light sensor 138 is AD-converted, and the differential height Δh can be measured by processing the interference intensity, for example, in the signal processing unit 190 (FIG. 1).

The DIC measurement of the interference light measurement device 130 can be performed simultaneously with (at the same scanning time) the scattered light measurement of the scattered light measurement device 120 by wavelength separation or spatial separation. Accordingly, it is possible to measure the surface of the sample 1 of the sample 1 at a higher speed. This also applies to a case where a surface shape measurement method other than the DIC measurement is applied to the measurement method of the interference light measurement device 130.

### [Signal Processing Device 200]

The signal processing device 200 is one or more computers that process signals of the scattered light measurement device 120 and the interference light measurement device 130. In the embodiment, the signal processing device 200 includes a data input unit 210, a data processing unit 220, and the signal processing unit 190 of the inspection device 100. For example, measurement data and the like for the sample surface, which is acquired by the detection optical system 122 and a detection optical system 130b and processed by the signal processing unit 190, is input to the data input unit 210. In the data processing unit 220, an evaluation value of the micro roughness of the sample 1 is calculated based on the data input to the data input unit 210. In the example of FIG. 1, the signal processing unit 190 of the inspection device 100 is provided in the signal processing device 200, and the signal processing device 200 is implemented by a plurality of computers. However, functions of the data input unit 210, the signal processing unit 190, and the data processing unit 220 may be provided in one computer, and the signal processing device 200 may be implemented by one computer.

### [Evaluation Procedure of Micro Roughness]

The evaluation of the micro roughness of the sample 1 executed by the data processing unit 220 will be described. In the embodiment, the signal processing device 200 (for example, the data processing unit 220) calculates a first evaluation value of the micro roughness of the sample 1 based on the signal of the interference light measurement device 130. At the same time, the signal processing device 200 calculates a scattering characteristic signal based on the signal of the scattered light measurement device 120, and calculates, for a spatial frequency band in which the first evaluation value is not calculated by the interference light measurement device 130, a second evaluation value of the micro roughness based on the first evaluation value and the scattering characteristic signal. In the embodiment, the signal processing device 200 calculates the first evaluation value and the second evaluation value of the micro roughness based on detection signals of the interference light and the scattered light generated at the same time.

The first evaluation value and the second evaluation value are values correlated with the micro roughness of the surface of the sample 1. The micro roughness can be calculated based on the first evaluation value and the second evaluation value. In an example described later, a case will be described in which power spectral density (PSD) data on the surface of the sample 1 as the first evaluation value and the second evaluation value and a haze value as the scattering characteristic signal are calculated.

An upper limit value of the spatial frequency band related to the second evaluation value calculated based on the scattering characteristic signal is higher than an upper limit value of the spatial frequency band related to the first evaluation value calculated based on the signal of the interference light measurement device 130. In particular, in the embodiment, an example will be described in which a lower limit value of the spatial frequency band related to the second evaluation value is higher than the upper limit value of the spatial frequency band related to the first evaluation value, and the spatial frequency band in which first PSD data can be acquired does not overlap the spatial frequency band in which second PSD data can be acquired.

The PSD data or the haze value can be obtained by dividing the entire surface of the sample 1 into a plurality of processing unit regions and processing each processing unit region in the signal processing unit 190. In order to evaluate the micro roughness with high accuracy, it is desirable to calculate the second evaluation value by the signal processing device 200 based on the first evaluation value (PSD data) and the scattering characteristic signal (haze value) related to the same region of the same sample.

When the surface shape of the sample 1 is represented by three-dimensional coordinates (X, Y, Z), it is possible to perform two-dimensional Fourier transform on the height Z in relation to (X, Y) and calculate, as a spatial frequency spectrum, a value obtained by squaring the amplitude. The spatial frequency spectrum is represented by a function P(fx, fy) having a reciprocal (fx, fy) of (X, Y) as a variable. The spatial frequency spectrum P(fx, fy) represented by fr is a PSD function P(fr). fr is a value obtained by fr=√(fx×fx+fy×fy).

The PSD function P(fr) includes information on a magnitude and a period of a surface roughness. That is, the PSD function is one of functions representing the spatial frequency spectrum. A value (PSD data) of the PSD function is substantially equivalent to data of the surface shape of the sample 1 related to the micro roughness. By integrating the PSD function P(fr) with any spatial frequency band (f1 to f2), a surface Rms roughness (root mean square roughness) of the sample 1 can be obtained.

The haze value is represented as a ratio of the scattered light signal S1 to an incident light amount on the beam spot 2 in the scattered light measurement device 120, and can be calculated by dividing the scattered light signal S1, which is measured by each of the scattered light intensity measurement systems 123 to 126, by the incident light amount. As the scattered light signal S1, a value of a signal output in real-time from the scattered light intensity measurement systems 123 to 126 can be used, and for example, a value stored in the signal processing unit 190 may be read out later and used.

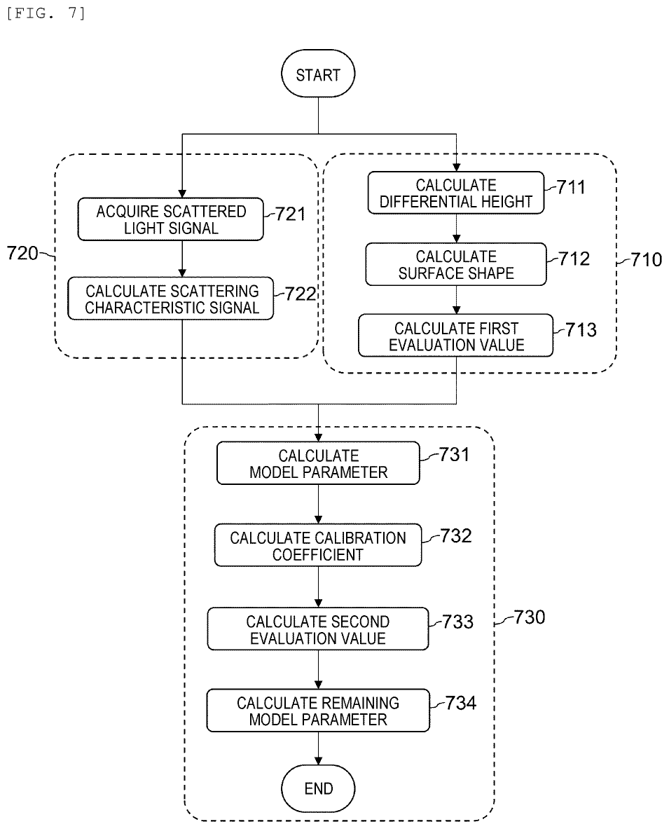

FIG. 7 is a flowchart showing an example of a procedure of processing of evaluating the micro roughness of the sample 1 by the signal processing device 200. The flow in the figure is roughly divided into processing 710 of calculating the first evaluation value of the micro roughness, processing 720 of calculating the scattering characteristic signal, and processing 730 of calculating the second evaluation value of the micro roughness. Although details will be described later, in the processing 710, the first evaluation value is calculated based on measurement data of the surface shape of the sample 1 based on the interference light. In the processing 720, the scattering characteristic signal having a predetermined spatial frequency in a predetermined spatial direction is calculated based on the signals of the plurality of scattered light intensity measurement systems 123 to 126. In the processing 730, the second evaluation value is calculated based on the first evaluation value and the scattering characteristic signal.

### —Processing 710—

The processing 710 of calculating the first evaluation value includes a step 711 of calculating the differential height Δh, a step 712 of calculating the surface shape of the sample 1, and a step 713 of calculating the first evaluation value.

### ⋅Step S711

The signal processing device 200 calculates the differential height Δh based on a change in phase of the two pieces of linearly polarized light 11 and 12 of the light emitted from the light source 131. At this time, in the embodiment, the light re-synthesized by the Nomarski prism 135 is separated by polarization of the polarization beam splitter 139, and is detected by the two interference light sensors 138. A time average of the interference intensity of the interference light detected by the polarization separation by the two interference light sensors 138 is calculated. The calculation accuracy of the differential height Δh can be improved by correcting phase shift of the pieces of linearly polarized light 11 and 12 based on the interference intensity of the calculated time average. The phase shift referred to here is a shift amount of a phase that occurs due to factors other than the differential height Δh, such as a gradient of the sample 1 and output variation of the light source 131, between the two pieces of linearly polarized light 11 and 12.

### ⋅Step S712

Next, the signal processing device 200 calculates the surface shape of the sample 1 based on the differential height Δh calculated in the step S711. The differential height Δh calculated in the step 711 is a difference in height between the polarization illumination spots 2a and 2b of the two pieces of linearly polarized light 11 and 12 separated by the shear amount d. Accordingly, the data of the surface shape of the sample 1 can be calculated by accumulating, for each shear amount δ, the data of the differential height Δh obtained by scanning.

### ⋅Step S713

In the subsequent step 713, the signal processing device 200 calculates the first evaluation value for the micro roughness based on the data of the surface shape of the sample 1 calculated in the step 712. In the embodiment, the data of the surface shape of the sample 1 calculated in the step 712 is subjected to Fourier transform to calculate the PSD data as the first evaluation value. Hereinafter, the PSD data as the first evaluation value calculated based on the signal of the interference light measurement device 130 is referred to as the “first PSD data”. In the embodiment, the first PSD data is calculated only in a shear direction, that is, only in a spatial direction the same as a straight line passing through centers of the two polarization illumination spots 2a and 2b. The spatial direction and the spatial frequency band of the first PSD data are determined by the method of measuring the surface shape of the sample 1 and the configuration of the interference light measurement device 130. For example, in the DIC measurement, an upper limit of the spatial frequency band is determined based on a sampling interval in the spatial direction and the Nyquist condition for a parameter having a large value among two parameters of the resolution of the optical system.

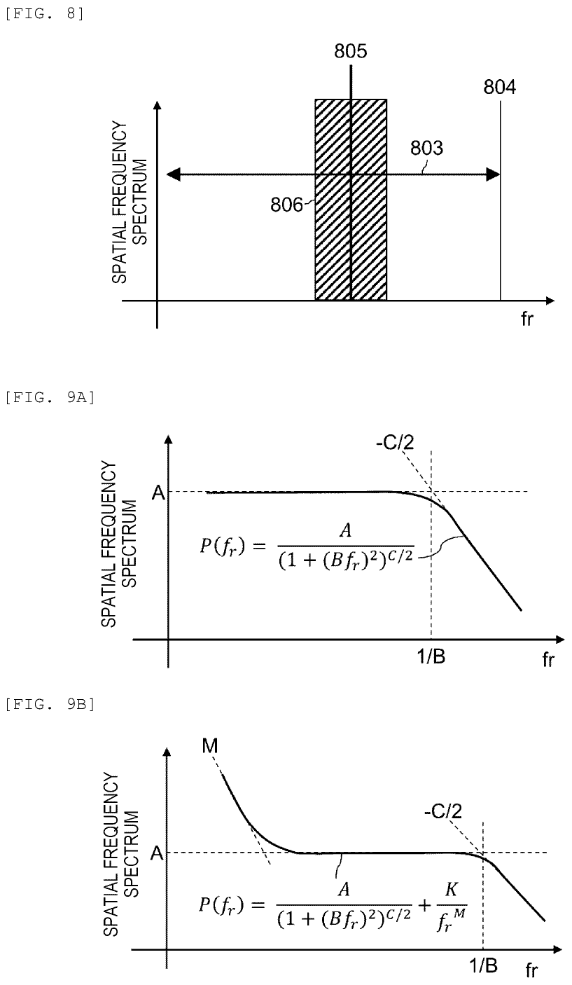

Here, in the DIC measurement, the sensitivity of the spatial frequency band corresponding to the shear amount & to the first PSD data is low. In the embodiment, since the shear amount d is larger than the optical resolution, there is a spatial frequency band that cannot be measured although the spatial frequency band is equal to or smaller than the upper limit of the spatial frequency of the first PSD data. This is shown in FIG. 8. In the figure, the horizontal axis represents fr, and the vertical axis represents a magnitude of the spatial frequency spectrum. An upper limit 804 of the spatial frequency band 803 which can be measured by the interference light measurement device 130 is determined based on the resolution of the optical system and the sampling interval as described above. Even in a band lower than the upper limit 804, for a predetermined band 806 including a spatial frequency 805 corresponding to the shear amount d, the sensitivity in principle of DIC that measures the difference in height (differential height Δh) between the two beam spots separated by the shear amount d is low. The first PSD data in the band 806 may not be calculated, but in the embodiment, interpolation may be performed based on the first PSD data around the band 806.

### —Processing 720—

Next, the processing 720 of calculating the haze value as the scattering characteristic signal based on the scattered light signal S1 will be described. The processing 720 includes a step 721 of acquiring the scattered light signal S1 and a step 722 of calculating the scattering characteristic signal based on the scattered light signal S1.

### ⋅Step 721

In the step 721, the signal processing device 200 acquires the scattered light signal S1 measured by the scattered light intensity measurement systems 123 to 126. As described above, as the scattered light signal S1, a value of a signal output in real-time from the scattered light intensity measurement systems 123 to 126 can be used, and for example, a value stored in the signal processing unit 190 may be read out later and used.

### ⋅Step 722

In the subsequent step 722, the signal processing device 200 divides the scattered light signal S1 of each of the scattered light intensity measurement systems 123 to 126 acquired in the step 721 by the incident light amount, for example, in the signal processing unit 190. This means calculating the ratio of the scattered light signal S1 of each of the scattered light intensity measurement systems 123 to 126 to the incident light amount. This signal ratio is a haze value.

### —Processing 730—

Next, the processing 730 of calculating the second evaluation value of the micro roughness based on the first evaluation value of the micro roughness and the scattering characteristic signal will be described.

In the embodiment, the haze value is converted into a bidirectional reflectance distribution function (BRDF) representing reflection and scattering characteristics of a substance surface, and is stored in the signal processing device 200 together with the BRDF. The BRDF includes information on the spatial frequency and the spatial direction. The BRDF is defined by the following (Formula 1) using an incident light amount Ii to the beam spot 2, the elevation angle θs of the scattered light flux, the solid angle ω, and a detected light amount Iω with reference to FIG. 4 described above.

$$\begin{matrix}[ Formula 1 ] & \\ BRDF = \frac{{I}_{ω}}{{I}_{i} ω cos {θ}_{s}} & Formula 1\end{matrix}$$

In addition, the BRDF can be modeled as shown in (Formula 2).

$$\begin{matrix}[ Formula 2 ] & \\ BRDF = \frac{16 {π}^{2}}{{λ}^{4}} cos {θ}_{i} cos {θ}_{s} Q \times PSD ( {f}_{x} , {f}_{y} ) & Formula 2\end{matrix}$$

θi is an elevation angle of an incident light flux to the beam spot 2, and λ is a wavelength of the incident light and the scattered light. Q is a parameter determined by a refractive index of the sample 1, the elevation angle θi of the incident light flux, and the elevation angle θs and the azimuthal angle φs of the scattered light flux. The spatial frequency fx, fy of the PSD function on the right side of (Formula 2) are represented as (Formula 3) using parameters of the incident light flux and the scattered light flux.

$$\begin{matrix}[ Formula 3 ] & \\ {f}_{x} = \frac{sin {θ}_{s} cos {ϕ}_{s} - sin {θ}_{i}}{λ} , {f}_{y} = \frac{sin {θ}_{s} sin {ϕ}_{s}}{λ} & Formula 3\end{matrix}$$

As shown in (Formula 1), the BRDF can be obtained based on a haze value (Iω/Ii) obtained by the scattered light measurement and parameters of the incident light flux and an emitted light flux. The BRDF has a relationship between the PSD function and (Formula 2). In the right side of (Formula 2), a term other than the PSD function is a parameter determined by the configurations of the inspection device 100 and the sample 1. Accordingly, in principle, PSD data of a predetermined spatial frequency in a predetermined spatial direction can be obtained from the haze value and the parameters of the inspection device 100 and the sample 1. In the embodiment, the PSD data calculated based on the haze value is referred to as the “second PSD data”.

However, the actually measured haze value changes depending on a reflectance of the sample 1, the output variation of the light source 131, and the like, and the second PSD data is affected by the change. As a result, a deviation may occur between the first PSD data and the second PSD data. Therefore, in order to quantitatively evaluate the micro roughness of the sample 1 using the first PSD data and the second PSD data, a calibration algorithm of the second PSD data is necessary.

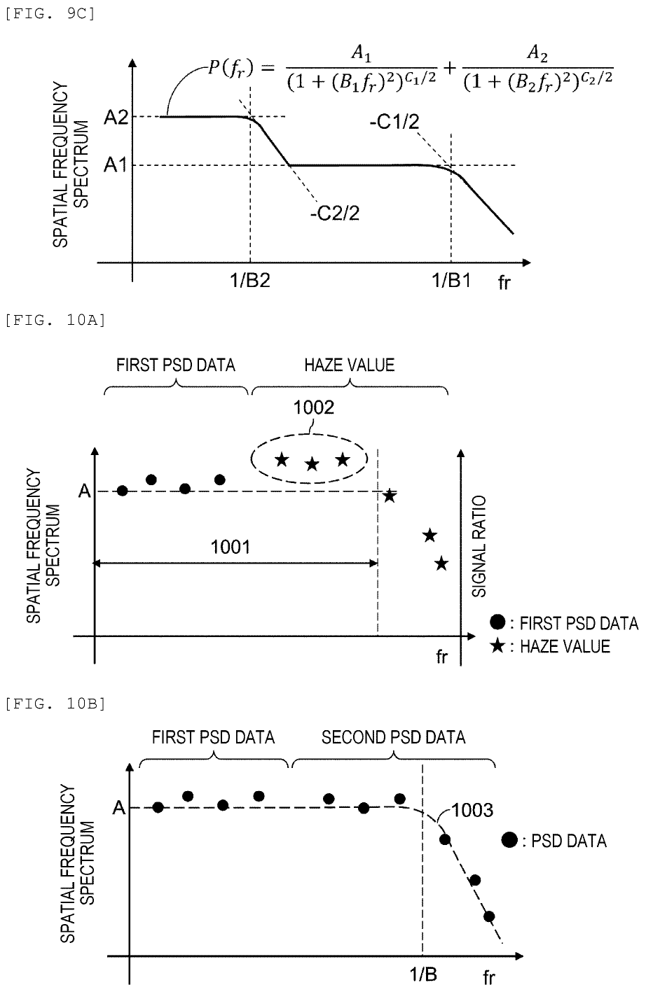

FIGS. 9A to 9C are diagrams of functions used in the PSD model. Each model shown in FIGS. 9A to 9C is represented by a double-logarithmic graph. The horizontal axis represents fr, and the vertical axis represents the magnitude of the spatial frequency spectrum.

A first PSD model shown in FIG. 9A is referred to as an ABC model. The ABC model can be represented by PSD(fr)=A/(1+Bfr²)^{C/2} using parameters A, B, and C for the spatial frequency fr of the surface roughness. In the ABC model related to the micro roughness, the PSD takes a constant value in a predetermined spatial frequency band (a band equal to or lower than 1/B) having a low frequency, and the PSD monotonously decreases according to fr in a band (a band equal to or higher than 1/B) having a high frequency. The constant value of the PSD in the band having a low frequency is A, the gradient of the PSD in the band having a high frequency is −C/2, and a spatial frequency of a branch point at which the PSD is changed from a constant value to a monotonic decrease is 1/B.

The ABC model is not limited to the example of FIG. 9A, and examples thereof include a second PSD model shown in FIG. 9B and a third PSD model shown in FIG. 9C. The ABC model shown in FIG. 9B is referred to as a fractal ABC model, and can be represented by PSD(fr)=A/(1+Bfr²)^{C/2}+K/fr^{M} using parameters A, B, C, K, and M. The fractal ABC model is characterized in that the PSD increases with a decrease in fr at an intercept K and a gradient −M in the low frequency band in the low frequency band in the ABC model shown in FIG. 9A. The ABC model shown in FIG. 9C is referred to as a double ABC model, and can be represented by PSD(fr)=A1/(1+B1fr²)^{C1/2}+A2/(1+B2fr²)^{C2/2} using parameters A1, B1, C1, A2, B2, and C2. The double ABC model is obtained by adding two different ABC models.

Based on the above, in the processing 730, the signal processing device 200 calculates the second PSD data based on the first PSD data and the haze value using the model functions shown in FIGS. 9A to 9C. In the embodiment, a case where the ABC model shown in FIG. 9A is used is described.

The processing 730 includes a step 731 to a step 734. Specifically, in the step 731, the signal processing device 200 calculates, based on the first PSD data, a part (in this example, A) of a model function parameter (hereinafter referred to as a model parameter) representing the PSD of the surface of the sample 1 for the ABC model. In the subsequent step 732, the signal processing device 200 calculates, based on a correspondence between the model parameter calculated in the step 731 and the haze value, a calibration coefficient used when converting the haze value into the PSD for the predetermined spatial direction and spatial frequency band. Then, in the step 733, the signal processing device 200 calibrates the haze value using a calibration count to calculate the second PSD data as the second evaluation value of the micro roughness of the sample 1. Finally, in the step 734, the signal processing device 200 calculates remaining model parameters based on the first PSD data and the second PSD data. In the processing 730, since the procedure of determining the model function, the spatial direction, the spatial frequency band, and the parameter used for the calculation differs depending on the characteristics of the sample 1 and the configuration of the inspection device 100, the procedure is not necessarily limited to the procedure shown in FIG. 7.

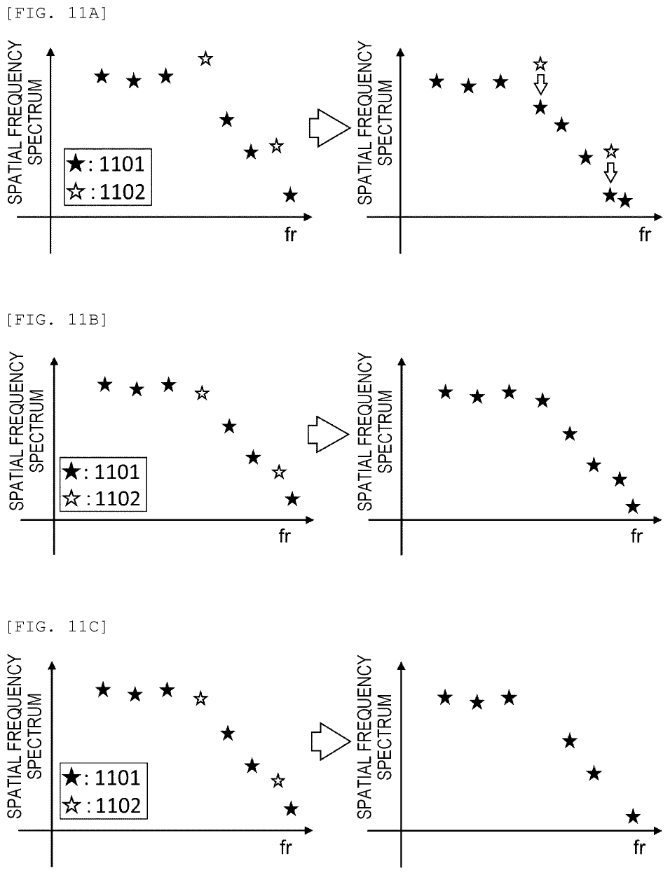

A graph shown in FIG. 10A is a double-logarithmic graph, the horizontal axis represents fr, the vertical axis (left) represents the magnitude of the spatial frequency spectrum, and the vertical axis (right) represents a signal ratio between the incident light amount and the scattered light signal. FIG. 10A shows the first PSD data represented by the frequency spectrum and the haze value represented by the signal ratio on the common horizontal axis. The steps 731 to 734 of the processing 730 shown in FIG. 7 will be described with reference to FIGS. 10A and 10B.

### ⋅Step 731

In the step 731 of the processing 730, the signal processing device 200 first calculates some model parameters for the model function in FIG. 9A, in this example, calculates the parameter A which is a constant value in the low frequency band based on the first PSD data. The parameter A can be calculated as a statistical value such as an average value or a central value of the first PSD data.

### ⋅Step 732

In the subsequent step 732, the signal processing device 200 calculates a calibration coefficient for converting a haze value included in a spatial frequency band 1001 represented by the parameter A, for example, a haze value 1002 equal to or lower than a predetermined spatial frequency set in advance, into the PSD represented by the parameter A. In this case, for example, the calibration coefficient is calculated such that a statistical value such as an average value or a central value of the haze value 1002 coincides with the PSD represented by the parameter A.

### ⋅Step 733

Next, in the step 733, the signal processing device 200 converts all the haze values including the haze value 1002 into the PSD data using the calculated calibration coefficient, and calculates the second PSD data. Accordingly, as shown in FIG. 10B, PSD data in both a frequency band that can be measured by the interference light measurement device 130 and a frequency band that can be measured by the scattered light measurement device 120 can be obtained. Specifically, the PSD data (first PSD data) in the frequency band that can be measured by the interference light measurement device 130 and the PSD data (second PSD data) in the frequency band that can be measured and expanded by cooperation of the interference light measurement device 130 and the scattered light measurement device 120 are acquired.

### ⋅Step 734

Next, in the step 734, the signal processing device 200 obtains the remaining model parameters B and C based on the second PSD data calculated in the step 733. If necessary, the Rms roughness can be calculated by integrating a model function 1003 constructed based on the parameters A, B, and C in any spatial frequency regions f1 to f2.

The signal processing device 200 outputs the data calculated in the processing shown in FIG. 7 to a display device (monitor) 230 at an appropriate time or sequentially, and displays a calculation process or a result by numerical values or graphics. Accordingly, an operator can confirm validity of the measurement and the calibration.

[Handling of Haze Value Whose Direction Is Different from Shear Direction]

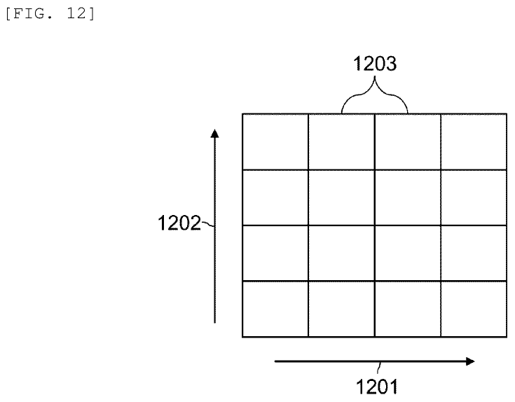

The signal processing device 200 calculates the second evaluation value based on the signal whose spatial direction corresponds to that of the first evaluation value among the scattering characteristic signals (the haze value corresponding to the micro roughness in the shear direction). Here, several types of handling of the haze value corresponding to the micro roughness in a direction different from the shear direction are shown with reference to FIGS. 11A to 11C. An example shown in FIG. 11A is referred to as a first example, an example shown in FIG. 11B is referred to as a second example, and an example shown in FIG. 11C is referred to as a third example. That is, the first example, the second example, and the third example are examples of how to handle the haze value whose spatial direction is different from that of the first evaluation value when calculating the second evaluation value. Each of the left and right diagrams shown in FIGS. 11A to 11C is a double-logarithmic graph. The horizontal axis represents fr, and the vertical axis represents the magnitude of the spatial frequency spectrum.

As described above, since the scattered light intensity measurement systems 123 to 126 each measure the scattered light in different spatial directions, a signal whose spatial direction coincides with that of the first PSD data is a signal of a specific scattered light intensity measurement system. In each of the left diagrams in FIGS. 11A to 11C, haze values 1101 whose spatial direction coincides with or has a predetermined approximation with that of the first PSD data, and haze values 1102 whose spatial direction is different from that of the first PSD data are mixed.

For convenience of illustration, the number of scattered light sensors 128 shown in FIGS. 1 and 3 is different from the number of haze values shown in the left diagrams in FIGS. 11A to 11C, but actually, the number is the same (for example, ten or more).

The first example shown in FIG. 11A is an example in which a correction coefficient set in advance is used according to the characteristics of the sample 1 and the configuration of the inspection device 100, and the haze value 1102 is corrected, by a difference generated between the haze values 1101 and 1102 due to the difference in the spatial direction, as indicated by a white arrow in the right diagram of the same figure. The correction coefficient in this case can be obtained by, for example, performing measurement by AFM in advance and comparing the measurement by the AFM and the scattered light measurement. The haze values 1101 shown in the right diagram of FIG. 11A including the values obtained by correcting the haze values 1102 are used for the calculation of the second evaluation value.

The second example shown in FIG. 11B is an example in which the haze value 1102 whose spatial direction is different from that of the first PSD data is handled similarly to the haze value 1101 whose spatial direction coincides with that of the first PSD data under the assumption that the micro roughness of the sample 1 is isotropic. The haze values 1102 are included in the basis of the calculation for the second evaluation value in the same manner as the haze values 1101 (right diagram in FIG. 11B), and the second evaluation value is calculated based on the haze values 1101 and 1102.

The third example shown in FIG. 11C is an example in which the haze values 1102 whose spatial direction is different from that of the first PSD data are excluded. The haze values 1102 are excluded from the basis of the calculation of the second evaluation value (right diagram in FIG. 11C), and the second evaluation value is calculated based only on the haze values 1101.

### [Others]

In the embodiment, the shear direction is a single direction, and the first PSD data is calculated only in the spatial direction the same as the single shear direction in the processing 710 (FIG. 7). That is, a case where the first evaluation value in the processing 710 is a one-dimensional value has been described. However, in the DIC measurement, it is not possible to obtain only a one-dimensional roughness evaluation value. For example, it is possible to adopt a configuration in which the Nomarski prism 135 in FIG. 6 is replaced with two Nomarski prisms whose polarization directions are orthogonal to each other, and is separated into four pieces of linearly polarized light having the shear amount d in the X direction and a Y direction, that is, the pieces of linearly polarized light 11 and 12 are further separated in the Y direction. In this configuration, two-dimensional first PSD data can be calculated.

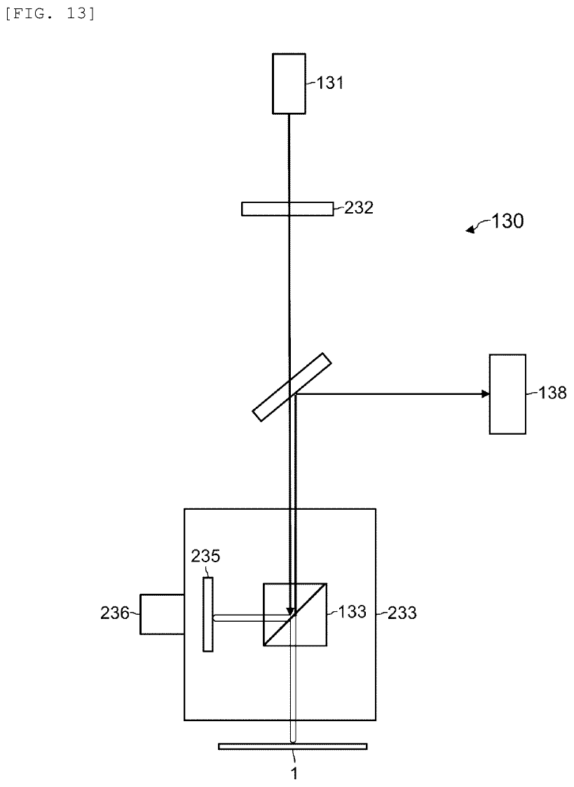

In addition, when flatness of the sample 1 is high as in the case where the sample 1 is a wafer, even if the shear direction is a single direction, the PSD data can be obtained even in a spatial direction (orthogonal direction 1202) orthogonal to a shear direction 1201 as shown in FIG. 12. FIG. 12 shows a part of the sample surface as a collection of rectangular sampling points 1203. In the embodiment, the differential height is accumulated in the shear direction 1201 to calculate the surface shape, that is, the height. In this case, the surface shape in the orthogonal direction 1202 can also be calculated by repeatedly scanning the sample 1. However, when there is an error in the setting of an initial value of accumulating calculation for the height, the accuracy is reduced by the error. On the other hand, when the flatness of the surface of the sample 1 is high, a setting error of the initial value can be prevented by the processing of the signal processing device 200. Consequently, the calculation accuracy of the surface shape of the sample 1 is improved. For example, the height is measured in a region of a setting area in which a certain degree of flatness can be expected, and by obtaining a statistical value (such as an average value) of the height, it is possible to adopt an initial value that is expected to have a certain degree of accuracy. In addition, processing such as smoothing or fitting may be performed at the sampling points 1203 adjacent to the orthogonal direction 1202. By increasing the setting accuracy of the initial value in this manner, it is possible to obtain highly reliable PSD data even in the orthogonal direction 1202.

### Effects

(1) The interference light measurement by the interference light measurement device 130 can be performed simultaneously (at the same scanning opportunity) with the scattered light measurement on the entire surface of the sample 1 by the scattered light measurement device 120, and the interference light and the scattered light can be measured at a high speed over the entire surface of the sample 1 of the sample 1. In particular, as shown in FIG. 2, when the sample 1 is rotated and scanned along a spiral trajectory, the measurement can be performed at a higher speed because the scanning does not involve a reciprocating operation.

Here, the interference light measurement can measure the micro roughness at a speed higher than that of the AFM generally used for the measurement of the micro roughness. On the other hand, the resolution is lower than that of the AFM. Therefore, from the viewpoint of the resolution, the measurement by the AFM cannot be simply replaced by the interference light measurement.

On the other hand, a maximum value of the spatial frequency of the micro roughness that can be measured by the scattered light is generally higher than a maximum value of the spatial frequency of the micro roughness that can be measured by the interference light. As described above, the interference light and the scattered light can also be measured simultaneously and at a high speed during scanning of the sample 1. Therefore, by calculating the second evaluation value of the micro roughness by the scattered light measurement for the spatial frequency band, in which the first evaluation value is not calculated, while calculating the first evaluation value of the micro roughness by the interference light measurement, it is possible to compensate for the shortage of the resolution due to the interference light measurement. At this time, as described above, a deviation may occur between a value based on the scattered light and a value based on the interference light. Therefore, it is not preferable to handle the values as they are, but in the embodiment, the deviation between the two values is also corrected by calculating the calibration coefficient as described above. Accordingly, the first evaluation value and the second evaluation value can be handled in the same manner. In addition, since the calibration coefficients can be sequentially calculated based on scanning data of the sample 1 by the scattered light measurement device 120 and the interference light measurement device 130, there is no need to separately collect basic data for calculating the calibration coefficients.

As described above, according to the embodiment, the first evaluation value and the second evaluation value are calculated at a high speed, and by calculating the second evaluation value in addition to the first evaluation value, the micro roughness of the entire surface of the sample can be measured at a high speed and a high resolution.

(2) In addition, in an inspection device for defect inspection of the sample, in order to detect light scattered in various directions from the sample surface, a celestial sphere centered on a beam spot may be divided into a plurality of regions, and a scattered light intensity measurement system (a scattered light sensor and the like) may be disposed for each region. In other words, by detecting scattered light for each spatial direction by a plurality of scattered light intensity measurement systems, it is possible to measure data of the scattered light having different spatial directions and spatial frequencies. The spatial direction and the spatial frequency of the micro roughness correlated with the haze value are determined by an incident angle, an emission angle, and a wavelength of the light to the sample surface. Therefore, by adding the interference light measurement device 130 to the inspection device for defect inspection, the sample surface quality management device can be configured, and the micro roughness in a wide spatial frequency band can be measured at a high speed by the cooperation of the scattered light measurement device 120 and the interference light measurement device 130.

### Second Embodiment

In a second embodiment, a case where a Michelson interferometer is used as a surface shape measurement method of the sample 1 is exemplified. In addition, in the embodiment, a spatial frequency band in which the first PSD data can be acquired and a spatial frequency band in which the second PSD data can be acquired partially overlap. That is, an upper limit value of the spatial frequency band related to the first evaluation value calculated based on the signal of the interference light measurement device 130 is lower than an upper limit value of the spatial frequency band related to the second evaluation value calculated based on the scattering characteristic signal as in the first embodiment, but higher than a lower limit value of the spatial frequency band related to the second evaluation value.

FIG. 13 is a schematic diagram showing a configuration example of the interference light measurement device 130 according to the embodiment. In FIG. 13, the same or corresponding elements as those in the first embodiment are denoted by the same reference signs as those in the already shown drawings, and the description thereof is omitted as appropriate.

The interference light measurement device 130 according to the embodiment includes the light source 131, a band-pass filter 232, an interference objective lens optical system 233, and the interference light sensor 138. The interference objective lens optical system 233 includes the beam splitter 133 and a reference surface (reflection mirror) 235. In addition, the interference objective lens optical system 233 is driven by a driving device 236, and is displaced, for example, in a direction advancing and retracting with respect to the sample 1. The interference light measurement device 130 according to the embodiment does not include the Nomarski prism 135.

In the embodiment, the light source 131 is a white light source. The light emitted from the light source 131 is incident on the interference objective lens optical system 233, and is separated into two pieces of light by the beam splitter 133. The separated one light is incident on the sample 1, and the other light is incident on the reference surface 235. The pieces of light reflected by the sample 1 and the reference surface 235 are synthesized by the beam splitter 133 and guided to the interference light sensor 138. In the embodiment, the interference light sensor 138 is a two-dimensional sensor. At this time, while the interference objective lens optical system 233 is displaced by the driving device 236, interference light intensities of the reflected light from the sample 1 and the reflected light from the reference surface 235 can be measured by the interference light sensor 138. Based on an interference light intensity distribution measured by the interference light sensor 138, the surface shape of the sample 1 is calculated by the signal processing device 200.

In the embodiment, two-dimensional height information of the surface of the sample 1 in a visual field is obtained at once. In a scanning method for the entire surface of the sample 1, similarly to the first embodiment, scanning in which rotation and straight advancing are combined (FIG. 2) or scanning in which straight advancing in two directions is combined can be applied.

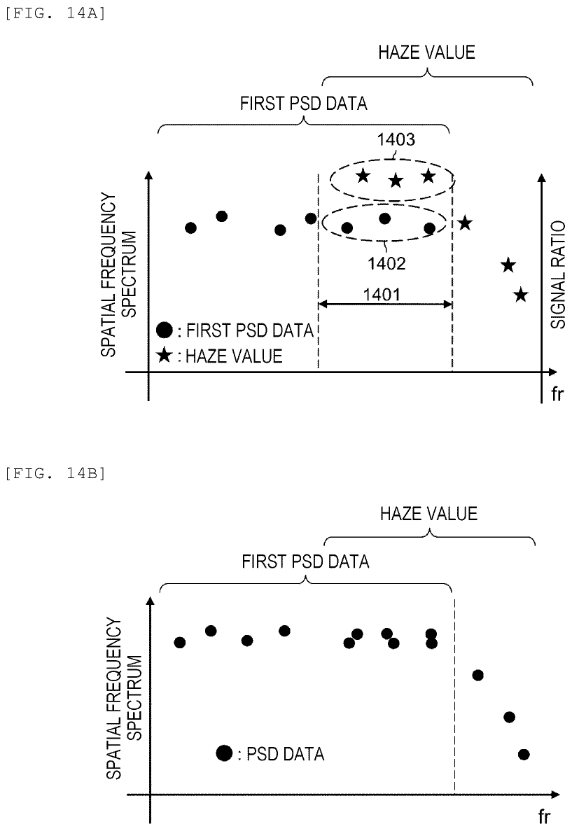

The processing 730 (FIG. 7) according to the embodiment will be described with reference to FIGS. 14A and 14B. A graph shown in FIG. 14A is a double-logarithmic graph, the horizontal axis represents fr, the vertical axis (left) represents a magnitude of a spatial frequency spectrum, and the vertical axis (right) represents a signal ratio between an incident light amount and a scattered light signal. FIG. 14A shows the first PSD data represented by the frequency spectrum and a haze value represented by the signal ratio on the common horizontal axis. A graph shown in FIG. 14B is also a double-logarithmic graph, the horizontal axis represents fr, and the vertical axis represents the magnitude of the spatial frequency spectrum.

As shown in FIG. 14A, in the embodiment, the spatial frequency band in which the first PSD data is measured and the spatial frequency band in which the haze value is measured overlap in a predetermined band 1401. That is, the upper limit value of the spatial frequency band in which the first PSD data is measured is lower than the upper limit value of the spatial frequency band in which the haze value is measured, but is higher than the lower limit value of the spatial frequency band in which the haze value is measured.

In the calculation of the second evaluation value in the embodiment, the signal processing device 200 first calculates a calibration coefficient used for conversion from the haze value to a PSD such that first PSD data 1402 and a haze value 1403 included in the predetermined band 1401 coincide with each other. For example, a statistical value such as an average value or a central value is obtained for each of the first PSD data 1402 and the haze value 1403, and the calibration coefficient is calculated such that the PSD based on the statistical value of the haze value 1403 coincides with the statistical value of the first PSD data 1402. Thereafter, the signal processing device 200 converts internal and external haze values of the predetermined band 1401 into the PSD using the calibration coefficient to calculate the second PSD data.

Accordingly, as shown in FIG. 14B, PSD data in a frequency band that can be measured by scattered light in addition to a frequency band that can be measured by interference light is obtained. If necessary, model parameters can also be obtained from the first PSD data and the second PSD data on the model function (ABC model and the like) as in the first embodiment. In addition, a micro roughness can also be calculated by integrating the model function in a predetermined spatial frequency band.

According to the embodiment, in addition to the same effects as those of the first embodiment, there is an advantage that two-dimensional height information of the surface of the sample 1 can be obtained at once by measuring the surface shape of the sample 1 using the Michelson interferometer.

In addition, the spatial frequency band of the first PSD data measured by the interference light partially overlaps the spatial frequency band of the second PSD data calculated based on the scattered light. Therefore, there is no need to use a model function to calculate the calibration coefficient. In other words, in the predetermined band 1401, a coincidence target of the second PSD data based on the haze value 1403 is the PSD data itself (second PSD data 1402) measured by the same inspection device 100. Therefore, it is expected to improve calculation accuracy of the second PSD data, and consequently, improve calculation accuracy of the micro roughness.

### Third Embodiment

In the first embodiment, the interference light measurement device 130 adopts the DIC measurement, separates the light emitted from the light source 131 into two pieces of linearly polarized light having a predetermined shear amount to irradiate the sample 1 with the pieces of light, and measures the interference intensity of the interference light generated in the sample 1 by the interference light sensor 138. This also applies to the embodiment. The embodiment is different from the first embodiment in that in the first embodiment, the shear amount δ of the DIC measurement is larger than the optical system resolution of the interference light measurement device 130, whereas in the embodiment, interference light of a shear amount smaller than the optical system resolution of the interference light measurement device 130 is used. Specifically, in the embodiment, the signal processing device 200 calculates the first evaluation value based on a signal related to interference light having a shear amount larger than the optical resolution of the interference light measurement device 130 and a signal related to interference light having a shear amount smaller than the optical resolution of the interference light measurement device 130. A specific example will be described with reference to the drawings.

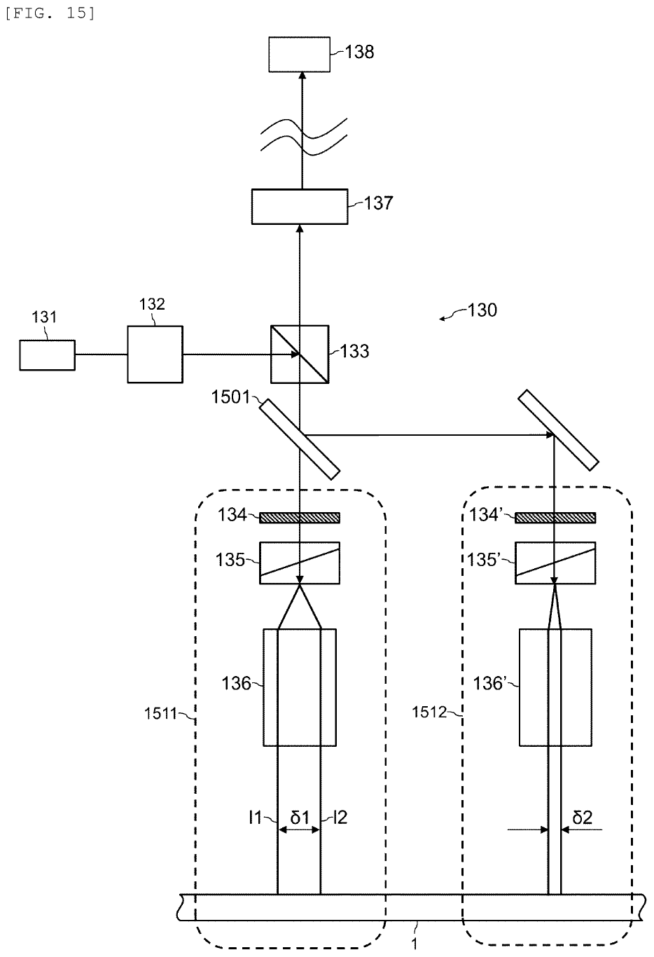

FIG. 15 is a schematic diagram showing a configuration example of an interference light measurement device provided in a sample surface quality management device according to the embodiment. In FIG. 15, the same or corresponding elements as those in the first embodiment are denoted by the same reference signs as those in the already shown drawings, and the description thereof is omitted as appropriate.

As in the first embodiment, the interference light measurement device 130 according to the embodiment includes the light source 131, the differential interference illumination system 132, the beam splitter 133, the ¼-wavelength plate 134, the Nomarski prism 135, the objective lens 136, the imaging lens 137, the interference light sensor 138, and the like. The interference light measurement device 130 according to the embodiment is different from the first embodiment in that the light source 131 is a multi-wavelength light source that emits two pieces of monochromatic light having different wavelengths, and obtains interference light for each monochromatic light.

The interference light measurement device 130 according to the embodiment includes a dichroic mirror 1501 as an optical element for separating light emitted from the light source 131 into two pieces of monochromatic light, and includes differential interference optical systems 1511 and 1512 corresponding to the two pieces of monochromatic light. The differential interference optical system 1511 is an optical s including the ¼-wavelength plate 134, the Nomarski prism 135, and the objective lens 136. The differential interference optical system 1512 is an optical system similar to the differential interference optical system 1511, and includes a ¼-wavelength plate 134′, a Nomarski prism 135′, and an objective lens 136′. However, a shear amount 81 of the Nomarski prism 135 is designed to be larger than the optical resolution of the interference light measurement device 130, and a shear amount 82 of the Nomarski prism 135′ is designed to be smaller than the optical resolution of the interference light measurement device 130.

In the embodiment, the light that has passed through the beam splitter 133 is separated into two pieces of monochromatic light by the dichroic mirror 1501. The pieces of monochromatic light are incident on differential interference optical systems 1511 and 1512, which obtain interference light in the same manner as in the first embodiment in the differential interference optical systems 1511 and 1512. The interference light is synthesized through the dichroic mirror 1501, and is incident on the interference light sensor 138. Although not particularly shown, the interference light can be separated according to the wavelength and measured by the plurality of interference light sensors 138.

Other configurations are the same as those of the first embodiment.

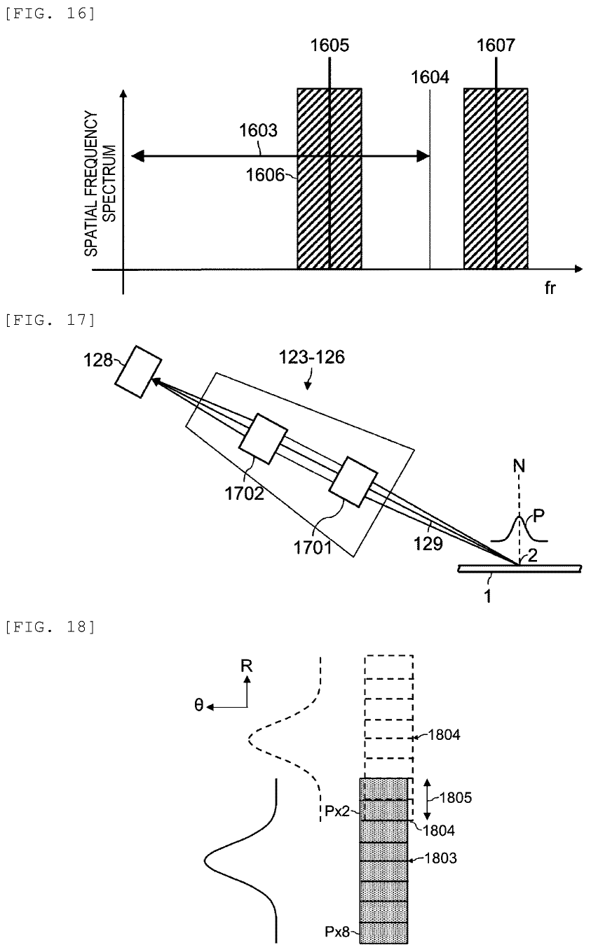

In the embodiment, the following effects are obtained in addition to the same effects as those of the first embodiment. The effect newly obtained in the embodiment will be described with reference to FIG. 16.

FIG. 16 is a diagram showing a spatial frequency band that cannot be measured by DIC measurement of the sample surface quality management device according to the third embodiment of the invention, and corresponds to FIG. 8 in the first embodiment. In the figure, the horizontal axis represents fr, and the vertical axis represents a magnitude of the spatial frequency spectrum. An upper limit 1604 of a spatial frequency band 1603 that can be measured by the interference light measurement device 130 according to the embodiment is determined based on the resolution and sampling interval of the optical system as described above. As described above, even in a band lower than the upper limit 804, sensitivity decreases in a predetermined band 1606 including a spatial frequency 1605 corresponding to the shear amount δ1.

However, in the embodiment, the differential interference optical system 1512 is provided in which the shear amount δ2 is smaller than the optical resolution. A spatial frequency 1607 corresponding to the shear amount δ2 is larger than the upper limit 1604. Therefore, the differential interference optical system 1512 can measure the entire spatial frequency band 1603 with appropriate sensitivity. On the other hand, in the differential interference optical system 1512 in which the shear amount δ2 is small, a contrast of the differential height measurement is reduced in principle.

In the embodiment, the differential interference optical system 1511 can measure the spatial frequency band 1603 excluding the band 1606 with a high contrast, and the differential interference optical system 1511 can measure the band 1606 whose sensitivity is reduced with a high sensitivity in the differential interference optical system 1512. As described above, according to the embodiment, the measurement can be performed with a high sensitivity in a spatial frequency band wider than in the first embodiment.

### Fourth Embodiment

FIG. 17 is a schematic diagram showing a configuration example of a scattered light intensity measurement system provided in a sample surface quality management device according to a fourth embodiment of the invention. In FIG. 17, the same or corresponding elements as those in the first embodiment are denoted by the same reference signs, and the description thereof is omitted as appropriate. In the embodiment, an example of a configuration and processing in a case where the scattered light intensity measurement systems 123 to 126 include imaging optical systems will be described.

As shown in FIG. 17, the scattered light intensity measurement systems 123 to 126 according to the embodiment include a condensing optical system 1701 for condensing scattered light from the surface of the sample 1, and an imaging optical system 1702 for condensing the image of the beam spot 2 on a light receiving surface of the scattered light sensor 128. Although not shown in FIG. 17, there is also a case where a driving device for focus adjustment which drives one of the sample 1, the condensing optical system 1701, the imaging optical system 1702, and the scattered light sensor 128 is provided.

As the scattered light sensor 128 according to the embodiment, as in the first embodiment, a photomultiplier tube, an avalanche photodiode array, and a photon counting array are considered as the sensor type. A point sensor, an area sensor, and a multi-line sensor can be used. In the embodiment, a line sensor is used as the scattered light sensor 128 as an example. In the scattered light sensor 128, a scattered light signal is obtained for each pixel.

In the processing 720 (FIG. 7), the signal processing device 200 calculates the haze value by dividing the scattered light signal by the uniform incident light amount in the first embodiment. However, in the embodiment, a haze value is calculated by dividing the scattered light signal by an incident light amount, which differs for each pixel of the scattered light sensor 128. The incident light amount for each sensor pixel is calculated based on an intensity profile of the beam spot 2 and parameters of the condensing optical system 1701 and the imaging optical system 1702.

FIG. 18 is a conceptual diagram showing a state in which beam spots partially overlap between adjacent scanning trajectories. Here, handling of a region measured twice or more in the scanning of the entire surface of the sample (that is, a region where the beam spot 2 overlaps between adjacent scanning trajectories) will be described.

The example shown in FIG. 18 is, for example, scanning of a spiral trajectory obtained by combining a rotation operation in the arrow θ direction and a straight advancing operation in the arrow R direction as shown in FIG. 2. In the embodiment, a width of the beam spot 2 is large in the R direction and small in the θ direction. Such an illumination profile can be generated by introducing a beam-shaping unit using an anamorphic prism or a cylindrical lens into the illumination optical system 121 of the scattered light measurement device 120.

FIG. 18 shows measurement regions 1803 and 1804 of the same 0 coordinate in the n-th and (n+1)-th cycles. An R coordinate of each of the measurement regions 1803 and 1804 is deviated by an interval of adjacent scanning trajectories, that is, an interval by which the straight advancing stage 113 moves during one rotation of the sample 1. In addition, FIG. 18 shows a case where the measurement regions 1803 and 1804 are divided and detected in eight pixels. In the embodiment, a length of the measurement region in the R direction is longer than the interval between the adjacent scanning trajectories, and an overlapping region 1805 of the measurement regions 1803 and 1804 is measured twice. For a measurement value of the overlapping region 1805, a method of using only one of measurement values of the measurement regions 1803 and 1804 or a method of integrating haze values related to the measurement values of the measurement regions 1803 and 1804 may be considered.

When the haze values related to the measurement values of the measurement regions 1803 and 1804 are integrated for the overlapping region 1805, first, a sum of a scattered light signal at the time of measurement at the n-th cycle and a scattered light signal at the time of measurement at the (n+1)-th cycle is taken for each pixel of the overlapping region 1805. At this time, the pixels of the overlapping region 1805 are different in the measurement at the n-th cycle and the measurement at the (n+1)-th cycle. In the overlapping region 1805, for example, coordinates measured at the second pixel Px2 from the top in the figure at the time of measurement at the n-th cycle are measured at the eighth pixel Px8 from the top at the time of measurement at the (n+1)-th cycle. Accordingly, for the coordinates, the scattered light signal of the pixel Px2 at the time of measurement at the n-th cycle and the scattered light signal of the pixel Px8 at the time of measurement at the (n+1)-th cycle are combined. Regarding the incident light amount, an incident light amount at the time of measurement at the n-th cycle and an incident light amount at the time of measurement at the (n+1)-th cycle are calculated and added for each pixel of the overlapping region 1805 based on a beam profile. Then, for each pixel of the overlapping region 1805, the sum of the scattered light signals at the time of measurement at the n-th cycle and the (n+1)-th cycle is divided by the sum of the incident light amounts at the time of measurement at the n-th cycle and the (n+1)-th cycle, and then the haze value is calculated.

In other respects, the embodiment is similar to the first embodiment.

According to the embodiment, in addition to the same effects as those of the first embodiment, there is an advantage that the calculation accuracy of the haze value of each coordinate on the surface of the sample 1 and the calculation accuracy of the second evaluation value are improved.

### Fifth Embodiment

In the first embodiment to the fourth embodiment, a case where the detection optical system 122 of the scattered light measurement device 120 includes the plurality of scattered light intensity measurement systems 123 to 126 is described. In the first embodiment to the fourth embodiment, by disposing the scattered light intensity measurement systems 123 to 126 in different spatial directions, the scattered light generated in the sample 1 is detected by the different scattered light sensors 128 according to the emission direction. On the other hand, the embodiment is an example in which only one scattered light sensor is provided in the detection optical system 122.

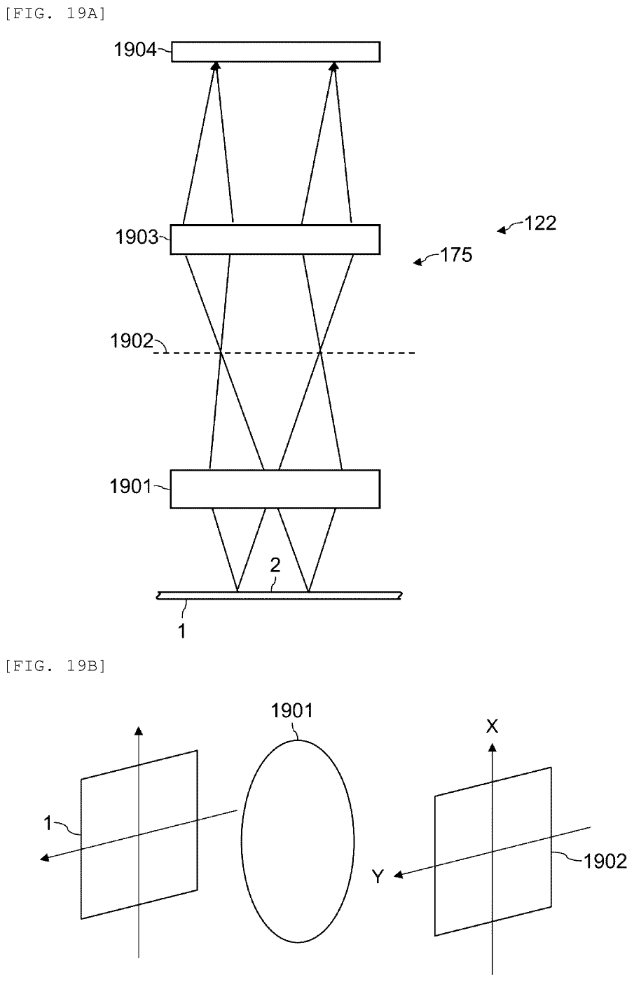

FIG. 19A is a schematic diagram showing a configuration example of a detection optical system of a scattered light measurement device provided in a sample surface quality management device according to a fifth embodiment of the invention. A configuration example of the detection optical system 122 including only one scattered light sensor will be described with reference to FIG. 19A.

The detection optical system 122 of the scattered light measurement device 120 according to the embodiment includes only one scattered light intensity measurement system 175. The scattered light intensity measurement system 175 includes a condensing optical system 1901, a detection optical system 1903, and a scattered light sensor 1904.

The scattered light generated at the beam spot 2 on the sample surface is condensed by the condensing optical system 1901. The detection optical system 1903 forms, on the scattered light sensor 1904, a pupil surface 1902 at a rear focal position of the condensing optical system 1901. The scattered light sensor 1904 according to the embodiment can apply a photomultiplier tube, an avalanche photodiode array, and a photon counting array as a sensor type in the same manner as in the first embodiment. An area sensor, a multi-line sensor, and the like can be used. In the embodiment, a two-dimensional array sensor is used as the scattered light sensor 1904.

FIG. 19B is a diagram showing a relationship between an emission direction of scattered light and pixel coordinates (X, Y) on the pupil surface 1902. In FIG. 19B, a scattered light emission angle corresponding to the pixel coordinates (X, Y) on the pupil surface 1902, that is, the coordinates (X, Y) can be obtained as follows.

$$\begin{matrix}[ Formula 4 ] & \\ X = f sin {θ}_{s} cos {ϕ}_{s} & Formula 4\end{matrix}$$

$$\begin{matrix}[ Formula 5 ] & \\ Y = f sin {θ}_{s} sin {ϕ}_{s} & Formula 5\end{matrix}$$

Here, f is a focal distance of the condensing optical system 1901. The definition of the scattered light emission angle is as described above with reference to FIG. 4. Coordinates on a light receiving surface of the scattered light sensor 1904 can be obtained by converting X and Y in Formulas 4 and 5 according to optical parameters of the detection optical system 1903. Accordingly, in combination with Formula 3, a spatial direction and a spatial frequency of a roughness corresponding to a haze value can be calculated for scattered light incident on each pixel on the light receiving surface of the scattered light sensor 1904 which is a two-dimensional array sensor.

According to the embodiment, an emission angle distribution of the scattered light can be measured by the single scattered light sensor 1904 by measuring a light intensity distribution of the pupil surface 1902. The corresponding spatial direction and spatial frequency band are different for each pixel of the scattered light sensor 1904. Therefore, in the processing 720 (FIG. 7) of the first to fourth embodiments, a specific pixel signal of the scattered light sensor 1904 is used instead of a scattered light signal of specific scattered light sensor corresponding to a target spatial direction, and the scattering characteristic signal and the second evaluation value can be calculated as in the first to fourth embodiments.

### Sixth Embodiment

Various types of data such as the first evaluation value and the second evaluation value acquired over the entire surface of the entire surface of the sample 1 in the first to fifth embodiments can be stored in a memory and displayed and output on the display device 230 (FIG. 1) by the signal processing device 200. In the embodiment, the display of data acquired over the entire surface of the entire surface of the sample 1 in the first to fifth embodiments is exemplified. As described in the first embodiment, the processing results such as the PSD data (FIG. 10B and the like) and the micro roughness (data obtained through the processing in FIG. 7) are calculated by the signal processing device 200 for each processing unit region by dividing the entire surface of the sample 1 into a plurality of processing unit regions. All the processing results for the processing unit regions can be used for display on the display device 230 (FIG. 1), or data statistically processed for a plurality of processing unit regions can be used for display.

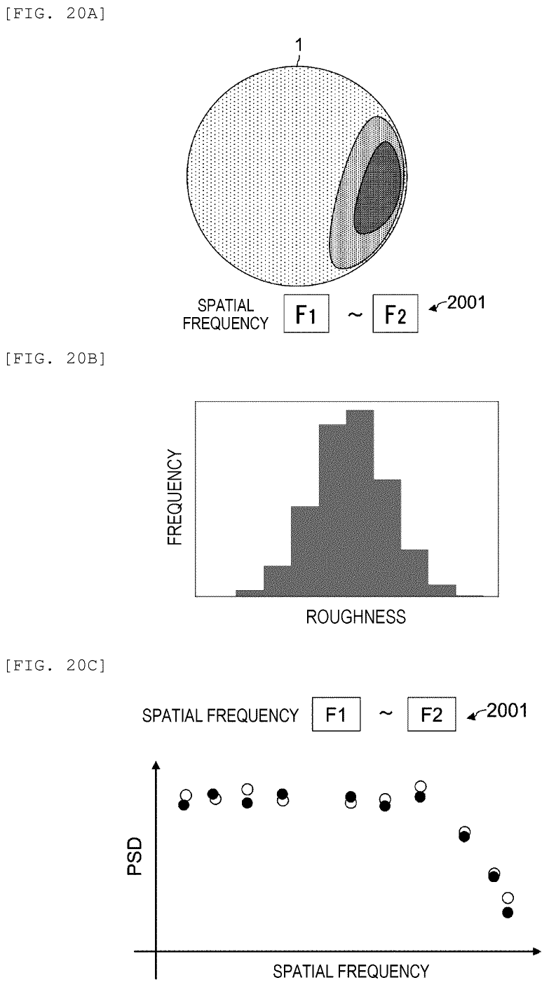

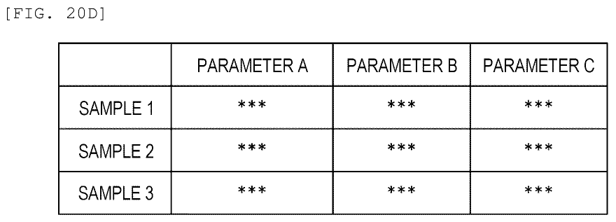

FIG. 20A is a diagram showing a display example in which a processing result is shown in a surface map of the sample 1 for each display unit region. FIG. 20A shows equipotential lines of the processing result (a height of the sample surface). For example, a method of displaying color-coded surface heights (numeric values) together with a color bar may be used. In addition, in the display example of FIG. 20A, an input field 2001 for designating a spatial frequency band of the processing result to be displayed is provided. FIG. 20A shows a method in which a lower limit value and an upper limit value of the spatial frequency band of the processing result to be displayed are designated by numerical values in the input field 2001. For example, other methods may be used, such as a method of designating a spatial frequency band using a control bar.

FIG. 20B is a diagram showing a display example in which a processing result is shown by a histogram. In the example of FIG. 20B, for example, a frequency (vertical axis) is displayed on the processing result (roughness) of the designated region of the sample surface designated by the input field (not shown). In addition to the frequency, a ratio and the like may be the vertical axis.

FIG. 20C is a diagram showing a display example in which a processing result (PSD data) is shown in a scatter diagram. In the example of FIG. 20C, PSD data (FIG. 10B and the like) calculated based on interference light and scattered light is displayed in a double-logarithmic graph by taking a spatial frequency as the horizontal axis and a magnitude of the PSD as the vertical axis. In the example of FIG. 20C, for example, PSD data of the spatial frequency band designated in the input field 2001 is displayed. FIG. 20C shows a method in which data of a plurality of samples 1 is plotted with different marks for each sample 1 and can be easily compared with eyes. In addition, a method of displaying a model function (the model function 1003 and the like of FIG. 10B) based on the calculated parameters may be adopted. According to the display example, an operator can easily select an appropriate type of the model function representing the PSD of the surface of the sample 1.

FIG. 20D is a diagram showing a display example in which a processing result (model parameters) is shown in a table format. In the example of FIG. 20D, only the model parameters calculated for the model function (the model function 1003 and the like of FIG. 10B) are displayed in a table format for each sample. In the case of the display example, it is possible to reduce data necessary for the display, and thus a data capacity required for micro roughness management for each sample.

### (Modification)

The invention is not limited to the above embodiments, and may include various modifications. For example, the above embodiments have been described in detail to facilitate understanding of the invention, and the invention is not necessarily limited to those including all the configurations described above. A part of a configuration according to a certain embodiment can be replaced with a configuration according to another embodiment, and a configuration according to another embodiment can be added to a configuration according to a certain embodiment. A part of a configuration according to each embodiment may be added, deleted, or replaced with another configuration.

Some or all of the above configurations, functions, processing, processing means, and the like may be implemented by hardware such as an integrated circuit. The above configurations, functions, and the like may be implemented by software by a processor interpreting and executing a program for implementing each function. Information such as programs, tables, and files for implementing the respective functions can be stored in various storage media. Examples of the various storage media include recording devices such as a memory, a hard disk, and a solid state drive (SSD), or a flash memory card and a digital versatile disk (DVD).

In the embodiments, signal input and output lines considered to be necessary for description are shown, and not all signal input and output lines in a product are necessarily illustrated. Actually, almost all configurations may be considered to be connected.

### REFERENCE SIGNS LIST

1: sample
110: stage device
120: scattered light measurement device
130: interference light measurement device
131: light source
200: signal processing device
230: display device
1401: predetermined band
11, 12: linearly polarized light
8, 82, 82: shear amount

1. A sample surface quality management device for measuring a micro roughness of a sample, the sample surface quality management device comprising:
a stage device configured to hold the sample and move the sample in a sample surface direction;
a scattered light measurement device configured to measure scattered light generated on the sample;
an interference light measurement device configured to measure interference light including reflected light generated on the sample; and
a signal processing device configured to process signals of the scattered light measurement device and the interference light measurement device, wherein
the signal processing device
calculates a first evaluation value of the micro roughness of the sample based on the signal of the interference light measurement device,
calculates a scattering characteristic signal based on the signal of the scattered light measurement device, and
calculates, for a spatial frequency band for which the first evaluation value is not calculated, a second evaluation value of the micro roughness based on the first evaluation value and the scattering characteristic signal.

2. The sample surface quality management device according to claim 1, wherein
the scattering characteristic signal is a haze value, and
the first evaluation value is PSD data.

3. The sample surface quality management device according to claim 1, wherein
the stage device moves the sample such that an entire surface of the sample is scanned.

4. The sample surface quality management device according to claim 1, wherein
an upper limit value of a spatial frequency band related to the second evaluation value calculated based on the scattering characteristic signal is higher than an upper limit value of a spatial frequency band related to the first evaluation value calculated based on the signal of the interference light measurement device.

5. The sample surface quality management device according to claim 1, wherein
the first evaluation value is calculated by a differential interference contrast method.

6. The sample surface quality management device according to claim 1, wherein
the interference light measurement device separates light emitted from a light source into two pieces of linearly polarized light having a predetermined shear amount, irradiates the sample with the light, and measures an interference intensity of interference light generated on the sample, and
the signal processing device calculates the first evaluation value based on a signal related to interference light having a shear amount larger than an optical resolution of the interference light measurement device and a signal related to interference light having a shear amount smaller than the optical resolution.

7. The sample surface quality management device according to claim 1, wherein
the signal processing device calculates the second evaluation value based on the first evaluation value and the scattering characteristic signal that are related to the same region of the same sample.

8. The sample surface quality management device according to claim 1, wherein
the signal processing device calculates the first evaluation value and the second evaluation value based on detection signals of the interference light and the scattered light that are generated at the same time.

9. The sample surface quality management device according to claim 1, wherein
the signal processing device
calculates, for a model function related to the micro roughness taking a constant value in a predetermined spatial frequency band, the constant value based on the first evaluation value,
calculates, based on the constant value and the scattering characteristic signal in the predetermined spatial frequency band, a calibration coefficient for converting the scattering characteristic signal into an evaluation value of the micro roughness, and
converts the scattering characteristic signal into the second evaluation value using the calibration coefficient.

10. The sample surface quality management device according to claim 1, wherein
a spatial frequency band related to the first evaluation value and a spatial frequency band related to the scattering characteristic signal overlap in a predetermined band, and
the signal processing device
calculates, based on the scattering characteristic signal and the first evaluation value in the predetermined band, a calibration coefficient for converting the scattering characteristic signal into an evaluation value of the micro roughness, and
converts the scattering characteristic signal into the second evaluation value using t the calibration coefficient.

11. The sample surface quality management device according to claim 1, wherein
the signal processing device calculates the second evaluation value based on a signal whose spatial direction corresponds to the first evaluation value among the scattering characteristic signals.

12. The sample surface quality management device according to claim 11, wherein
the signal processing device corrects, by a preset correction coefficient, a signal whose spatial direction is different from the first evaluation value among the scattering characteristic signals, and includes the corrected signal in a basis for calculation of the second evaluation value.

13. The sample surface quality management device according to claim 11, wherein
the signal processing device includes, in a basis for calculation of the second evaluation value, a signal whose spatial direction is different from the first evaluation value among the scattering characteristic signals, similarly to the signal whose spatial 1 direction corresponds to the first evaluation value.

14. The sample surface quality management device according to claim 11, wherein
the signal processing device excludes, from a basis for calculation of the second evaluation value, a signal whose spatial direction is different from the first evaluation value among the scattering characteristic signals.

15. The sample surface quality management device according to claim 1, further comprising:
a display device configured to display the first evaluation value and the second evaluation value.
